(19) United States
(12) Patent Application Publication
(10) Pub. No.: US 2009/0050978 A1
(43) Pub. Date: Feb. 26, 2009

(54) SEMICONDUCTOR DEVICE

(76) Inventor: Naohiro Ueda, Hyogo (JP)

Correspondence Address: COOPER & DUNHAM, LLP, 30 Rockefeller Plaza, 20th Floor, NEW YORK, NY, 10112, US

(21) Appl. No.: 11/914,872

(22) PCT Filed: Mar. 12, 2007
(86) PCT No.: PCT/JP2007/055324

§ 371 Date: Nov. 19, 2007

(30) Foreign Application Priority Data
Mar. 31, 2006 (JP) 2006-098393

(51) Int. Cl. H01L 27/088

(52) U.S. Cl. 257/392; 257/E27.06

(57) ABSTRACT

A disclosed semiconductor device includes a driver transistor including a source and a drain of a second conductive type provided with an interval therebetween in a semiconductor substrate of a first conductive type, a gate electrode extending in a predetermined direction and provided on the semiconductor substrate via a gate insulating film between the source and the drain, plural insular back gate diffusion layers of the first conductive type provided in the source so as to be in contact with the semiconductor substrate, wherein the back gate diffusion layers are spaced apart and arranged in the predetermined direction in the source, and a contact hole extending in the predetermined direction on the source and at least one of the back gate diffusion layers.

### TECHNICAL FIELD

The present invention relates to semiconductor devices, and in particular, to a semiconductor device provided with a driver transistor configured with a MOS (Metal Oxide Semiconductor) transistor.

### BACKGROUND ART

There are transistors referred to as driver transistors functioning as MOS transistors. The term driver transistor used herein refers to “a transistor with a relatively wide channel width for driving an element of a next stage”. As an example of a driver transistor, a charging circuit often used in mobile phones is described below.

FIGS. 9A, 9B are schematic circuit diagrams of a charging device. A rechargeable battery 31 is connected to a power supply 35 (corresponding to a household AC socket) via a charging switch 33. FIG. 9A shows a status before the rechargeable battery 31 is charged and a transistor 37 is turned off. The transistor 37 needs to be turned on to perform a charging operation. When the transistor 37 is turned on, the charging switch 33 connected to the transistor 37 via an electrode pad 23 is turned on, and a current A flows from the power supply 35 to the rechargeable battery 31, so that the rechargeable battery 31 is charged (see FIG. 9B).

In this circuit, the transistor 37 is serving as a driver transistor. That is, the transistor 37 is driving the charging switch 33, which is an element of a next stage. Furthermore, the larger the current A, the faster the charging operation is completed. Accordingly, a current B flowing through the transistor 37 that drives the charging switch 33 also needs to be large. A current flowing through a transistor is proportional to the channel width of the transistor, and therefore, the transistor 37 serving as the driver transistor is designed to have a wide channel.

Next, the layout of the driver transistor is described. FIGS. 10A-10C illustrate a typical driver transistor forming area including an electrode pad forming area. FIG. 10A is a plan view, FIG. 10B is a schematic plan view, and FIG. 10C is a cross-sectional view taken along line X-X of FIG. 10B.

A LOCOS oxide film 3 is formed on a P-type silicon substrate 1 to define a driver transistor forming area 5. Sources 7s and drains 7d configured with N-type impurity diffusion layers are formed in the driver transistor forming area 5 in the silicon substrate 1. The sources 7s and the drains 7d are arranged alternately with intervals therebetween in the widthwise direction.

In between the sources 7s and the drains 7d, gate electrodes 11 made of polysilicon are formed on the silicon substrate 1 via gate oxide films 9. The gate electrodes 11 are formed in areas between the plural sources 7s and drains 7d. There are four gate electrodes 11 illustrated in FIGS. 10B and 10C; however, several tens of the gate electrodes 11 are generally provided in order to make the driver transistor have a wide channel.

In the silicon substrate 1, a back gate diffusion layer 7b configured with a P-type impurity diffusion layer surrounds the area where the sources 7s and the drains 7d,are formed. The back gate diffusion layer 7b is used for extracting the substrate potential.

An interlayer insulating film 13 (omitted from FIGS. 10A, 10B) is formed on the entire surface of the silicon substrate 1, including the area where the sources 7s, the drains 7d, the gate electrodes 11, and the back gate diffusion layer 7b are formed. In the interlayer insulating film 13 and above the sources 7s, contact holes 15s are formed. In the interlayer insulating film 13 and above the drains 7d, contact holes 15d are formed. In the interlayer insulating film 13 and above the back gate diffusion layer 7b, a contact hole 15b is formed. In the interlayer insulating film 13 and above the gate electrodes 11, contact holes are formed (not shown).

A comb-like metal wiring layer 17s is formed on the interlayer insulating film 13 including areas where the contact holes 15s are formed above the sources 7s. The plural sources 7s are electrically connected with each other via the contact holes 15s and the metal wiring layer 17s. The metal wiring layer 17s is connected to an electrode pad 23s formed on the interlayer insulating film 13 in the electrode pad forming area provided near the driver transistor forming area.

A comb-like metal wiring layer 17d is formed on the interlayer insulating film 13 including areas where the contact holes 15d are formed above the drains 7d. The plural drains 7d are electrically connected with each other via the contact holes 15d and the metal wiring layer 17d. The metal wiring layer 17d is connected to an electrode pad 23d formed on the interlayer insulating film 13 in the electrode pad forming area.

A metal wiring layer 17b is formed on the interlayer insulating film 13 including an area where the contact hole 15b is formed above the back gate diffusion layer 7b.

A metal wiring layer is formed in an area (not shown) including the contact holes above the gate electrodes 11. The plural gate electrodes 11 are electrically connected with each other via the not shown contact holes and the metal wiring layer.

A final protection film 19 is formed on the interlayer insulating film 13. The final protection film 19 includes pad openings 21s, 21d provided on the electrode pads 23s, 23d.

FIGS. 10A-10C illustrate a single layer metal wiring structure; however, multilayer wirings of two or more layers. have become mainstream in recent years and continuing.

The salient feature of a driver transistor is that the sources 7s and the drains 7d are alternately arranged on both sides of the gate electrodes 11, as shown in FIGS. 10A-10C. When the driver transistor is turned on, currents flow in directions indicated by arrows shown in FIG. 10C. Specifically, each of the sources 7s and the drains 7d applies functions on the gate electrodes 11 provided on both sides thereof, and therefore, the driver transistor can be laid out such that a large current can flow through a small area.

Furthermore, another feature of the driver transistor is that the back gate diffusion layer 7b is formed along the periphery of the driver transistor forming area 5, like a frame.

The role of the back gate diffusion layer 7b is discussed below. The back gate diffusion layer 7b is arranged to provide a predetermined potential to the P-type silicon substrate 1. In this examples GND potential (zero volts potential) is applied to the back gate diffusion layer 7b and the P-type silicon substrate 1.

Theoretically, when GND potential is applied to the back gate diffusion layer 7b, the back gate diffusion layer 7b and the P-type silicon substrate 1 are supposed to become entirely GND potential. However, in reality, the following phenomenon occurs in the driver transistor.

As described above, a driver transistor is typically designed to have an extremely wide channel, e.g., 100 thousand μm or more, so that a large current can flow through. The channel is not only wide in a widthwise direction (vertical direction as viewed in FIGS. 10A-10C), but is also long in a lengthwise direction (horizontal direction as viewed in FIGS. 10A-10C). As a result, the layout area of the driver transistor becomes very large.

If the layout area of the driver transistor is large, the substrate potential of the driver transistor at a portion far away from the back gate diffusion layer 7b would deviate from an ideal level. This is primarily because the impurity density of the P-type silicon substrate 1 is low, and the resistance value is high. FIGS. 11A-11C illustrate a failure of a conventional driver transistor. FIG. 11A only shows the back gate diffusion layer 7b in the driver transistor forming area 5 as a matter of convenience.

As shown in FIGS. 11A, 11B, because a substrate resistance 21 is large, the substrate potential at a portion of the driver transistor that is far away from the back gate diffusion layer 7b becomes significantly higher than the rest of the driver transistor. Accordingly, the portion that is furthest from the back gate diffusion layer 7b, i.e., a portion around the center of the driver transistor forming area 5, would obviously have the highest potential.

If the substrate potential is not completely. fixed and the potential rises, a parasitic bipolar transistor of the driver transistor starts operating, and a shortmode status occurs between the sources and the drains. Then, a large current flows in between the sources and the drains at once, which causes a thermal breakdown in the driver transistor. FIG. 11C illustrates a thermal breakdown in the driver transistor that is detected with an evaluation pattern. The breakdown has occurred in the center of the driver transistor forming area, which is consistent with the above description.

Such a thermal breakdown caused by a parasitic bipolar transistor is a fatal failure in the transistor. This not only breaks the elements but may also cause the IC to ignite or fume, which may lead to a serious accident. Thus, it is imperative for IC manufacturers to ensure that the parasitic bipolar transistor does not start operating.

There are several methods of preventing the parasitic bipolar transistor from operating. With a method involving the design of the circuit layout, the parasitic bipolar transistor can be prevented from operating without changing the structure of the transistor. An example is described below.

A method of arranging the back gate diffusion layer also in the middle of the driver transistor is described with reference to FIGS. 12A, 12B (see, for example, Patent Document 1). In Patent Document 1, the back gate diffusion layer is referred to as a diffusion layer serving as a substrate contact. In FIG. 12A, only a silicon substrate, an impurity diffusion layer, and contact holes are shown.

As shown in FIGS. 12A, 12B, sources at the center of the driver transistor forming area 5 are divided into a source 7s-1 and a source 7s-2, and a back gate diffusion layer 7b-1 is arranged therebetween. Accordingly, the substrate potential can be fixed even in the center of the driver transistor forming area 5, where it is far away from the periphery.

A method of arranging a back gate diffusion layer inside the sources is described with reference to FIGS. 13A, 13B (see, for example, Patent Document 2). In Patent Document 2, a structure including a diffusion layer, corresponding to the back gate diffusion layer described above, is referred to as a butted contact structure. In FIG. 13A, only a silicon substrate, an impurity diffusion layer, and contact holes are shown.

As shown in FIGS. 13A, 13B, back gate diffusion layers 7b-2 are formed in the same area as the sources 7s. The difference between the conventional example shown in FIGS. 12A, 12B is that the sources 7s (N-type diffusion layer areas) and the back gate diffusion layers 7b-2 (P-type diffusion layer areas) contact each other. Such a source in which an N-type diffusion layer area is adjacent to a P-type diffusion layer area is referred to as a “butting source”.

As shown in FIG. 13B, the back gate diffusion layers 7b-2 are connected to the metal wiring layers 17s. The metal wiring layers 17s are electrically connected to the sources 7s via the contact holes 15b. Accordingly, the sources 7s and the back gate diffusion layers 7b, 7b-2 have the same potential. As shown in FIGS. 9A, 9B, the sources 7s are connected to GND potential, and can thus be connected by the same metal as that of the back gate diffusion layers 7b, 7b-2.

However, the above conventional technologies have the following problems. In the conventional example shown in FIGS. 12A, 12B, the back gate diffusion layer 7b-1 is added in the middle of the driver transistor forming area 5, thus-increasing the layout area. The driver transistor already occupies a large area, and with the addition of the back gate diffusion layer 7b-1, the area becomes even larger. This leads to a larger chip area and higher chip costs.

Furthermore, in the conventional example shown in FIGS. 13A, 13B, another disadvantage is caused unless the butting sources are laid out appropriately.

FIG. 14 is a graph indicating the relationship between the current driving ability (Idsat) and the distance (space) between the P-type back gate diffusion layer and the gate electrode in the conventional driver transistor having a butting source structure. The vertical axis represents the current driving ability (mA) and the horizontal axis represents the distance between the P-type back gate diffusion layer and the gate electrode (μm).

As shown in this graph, when the distance between the P-type back gate diffusion layer and the gate electrode is 2.0 μm or less, the current driving ability is lower. By employing butting sources, it is possible to fix the substrate potential even in the center of the driver transistor forming area where it is far away from the periphery. However, the current driving ability decreases, which is the most important aspect of a driver transistor. In order to compensate for the decrease in the current driving ability, the channel width needs to be increased by an amount corresponding to the decrease. As a result, the layout area becomes disadvantageously large.

Patent Document 1: Japanese Laid-Open Patent Application No. H6-275802

Patent Document 2: Japanese Laid-Open Patent Application No. HB-288401

Accordingly, there is a need for a semiconductor device provided with a driver transistor in which the voltage at which a parasitic bipolar transistor of the driver transistor starts operating is made high (high breakdown voltage) without decreasing the current driving ability of the driver transistor.

### DISCLOSURE OF THE INVENTION

The present invention provides a semiconductor device in which one or more of the above-described disadvantages are eliminated.

An embodiment of the present invention provides a semiconductor device including a driver transistor including a source and a drain of a second conductive type provided with an interval therebetween in a semiconductor substrate of a first conductive type, a gate electrode extending in a predetermined direction and provided on the semiconductor substrate via a gate insulating film between the source and the drain, plural insular back gate diffusion layers of the first conductive type provided in the source so as to be in contact with the semiconductor substrate, wherein the back gate diffusion layers are spaced apart and arranged in the predetermined direction in the source, and a contact hole extending in the predetermined direction on the source and at least one of the back gate diffusion layers.

### BRIEF DESCRIPTION OF THE DRAWINGS

FIGS. 1A-1C illustrate an embodiment of the present invention; FIG. 1A is a plan view of a driver transistor forming area, FIG. 1B is a cross-sectional view taken along line A-A of FIG. 1A, and FIG. 1C is a cross-sectional view taken along line B-B of FIG. 1A;

FIGS. 2A-2C illustrate another embodiment of the present invention; FIG. 2A is a plan view of the driver transistor forming area, FIG. 2B is a cross-sectional view taken along line A-A of FIG. 2A, and FIG. 2C is a cross-sectional view taken along line B-B of FIG. 2A;

FIGS. 3A-3C illustrate yet another embodiment of the present invention; FIG. 3A is a plan view of the driver transistor forming area, FIG. 38 is a cross-sectional view taken along line A-A of FIG. 3A, and FIG. 3C is a cross-sectional view taken along line B-B of FIG. 3A;

FIGS. 4A-4C illustrate yet another embodiment of the present invention; FIG. 4A is a plan view of the driver transistor forming area, FIG. 4B is a cross-sectional view taken along line A-A of FIG. 4A, and FIG. 4C is a cross-sectional view taken along line B-B of FIG. 4A;

FIGS. 5A-5C illustrate yet another embodiment of the present invention; FIG. 5A is a plan view of the driver transistor forming area, FIG. 5B is a cross-sectional view taken along line A-A of FIG. 5A, and FIG. 5C is a cross-sectional view taken along line B-B of FIG. 5A;

FIGS. 6A-6C illustrate yet another embodiment of the present invention; FIG. 6A is a plan. view of the driver transistor forming area, FIG. 6B is a cross-sectional view taken along line A-A of FIG. 6A, and FIG. 6C is a cross-sectional view taken along line B-B of FIG. 6A;

FIGS. 7A, 7B are graphs illustrating results obtained by measuring the voltage at which the parasitic bipolar transistor starts operating (breakdown voltage) and the current driving ability of the embodiments of the present invention and a conventional example; FIG. 7A illustrates the breakdown voltages and FIG. 7B illustrates the current driving abilities;

FIG. 8 is a circuit diagram of an embodiment of a semiconductor device provided with a constant-voltage generating circuit, which is an analog circuit;

FIGS. 9A, 9B are schematic circuit diagrams of a charging device employing a conventional driver transistor;

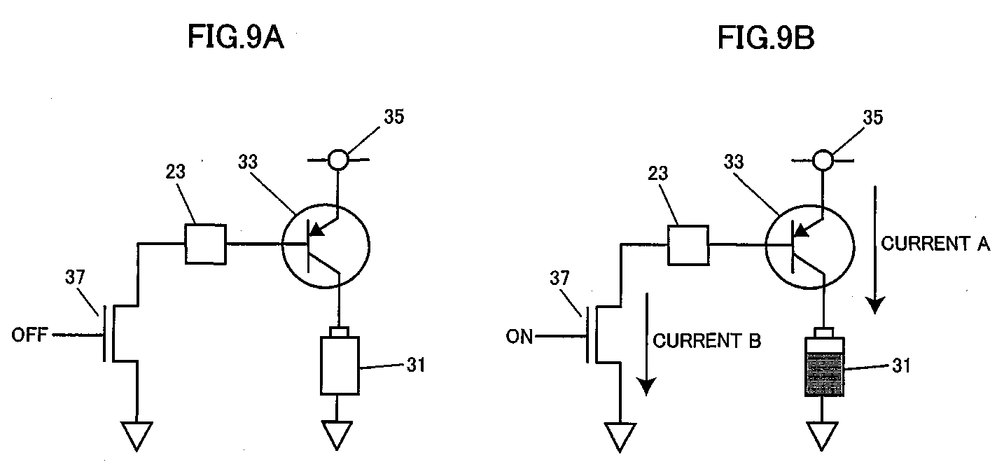

FIGS. 10A-10C illustrate a conventional driver transistor forming area including an electrode pad forming area; FIG. 10A is a plan view, FIG. 10B is a schematic plan view, and FIG. 10C is a cross-sectional view taken along line X-X of FIG. 10B;

FIGS. 11A-11C illustrate a failure of a conventional driver transistor;

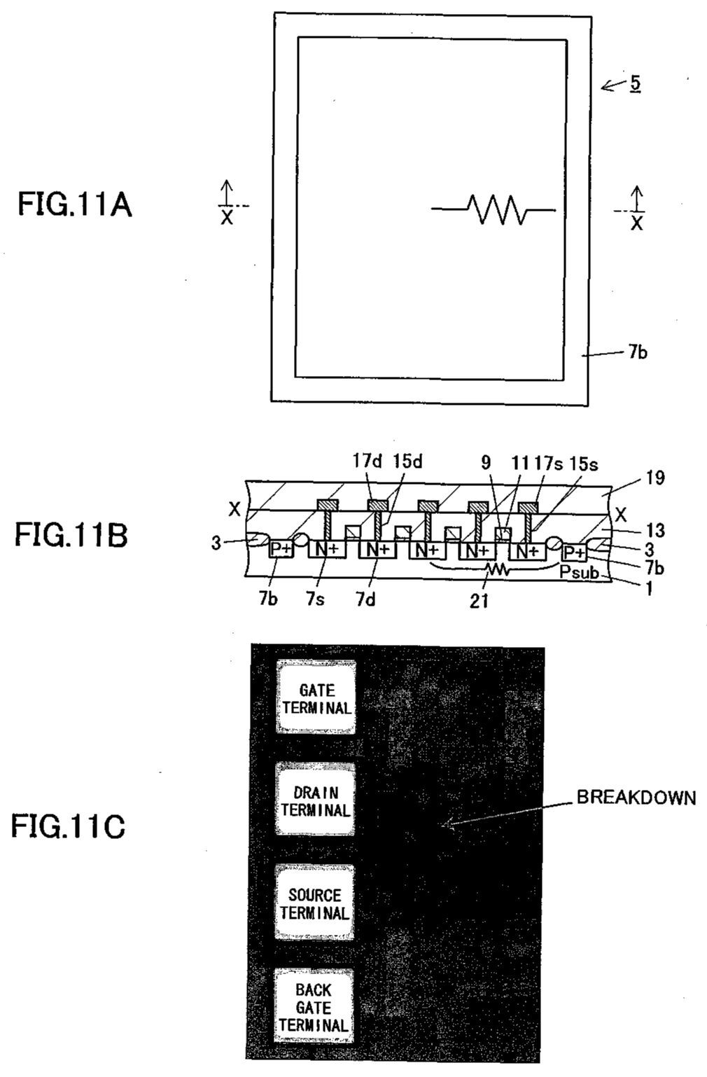

FIGS. 12A, 12B illustrate a conventional driver transistor; FIG. 12A is a plan view and FIG. 12B is a cross-sectional view taken along line X-X of FIG. 12A;

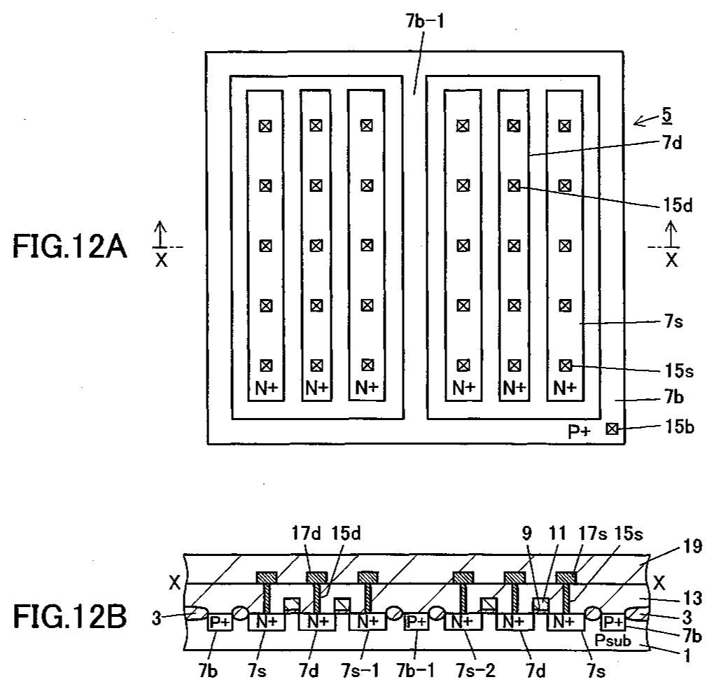

FIGS. 13A, 13B illustrate another conventional driver transistor; FIG. 13A is a plan view and FIG. 13B is a cross-sectional view taken along line X-X of FIG. 13A; and

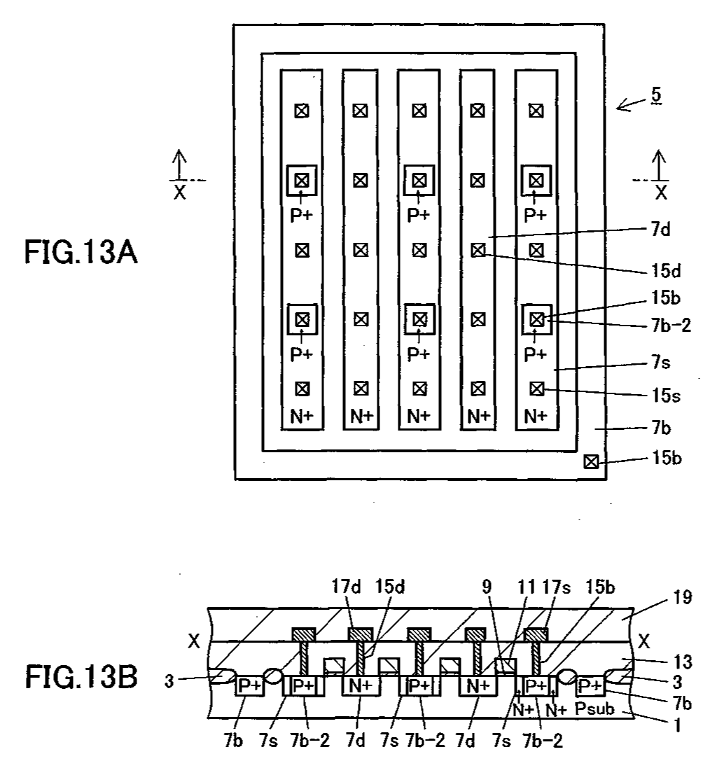

FIG. 14 is a graph indicating the relationship between the current driving ability and the distance (space) between the P-type back gate diffusion layer and the gate electrode in the conventional driver transistor shown in FIGS. 13A, 13B.

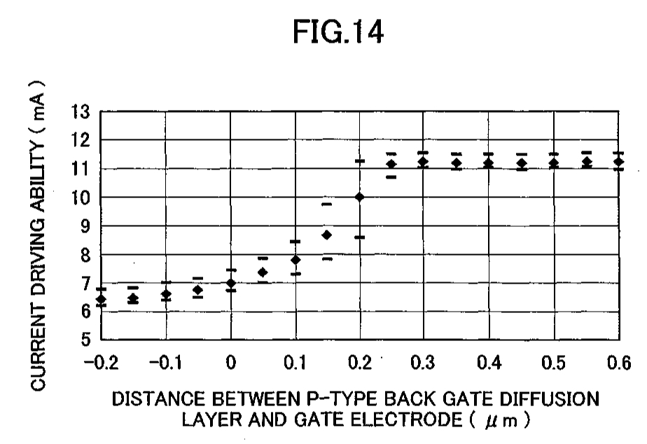

### BEST MODE FOR CARRYING OUT THE INVENTION

A description is given, with reference to the accompanying drawings, of an embodiment of the present invention.

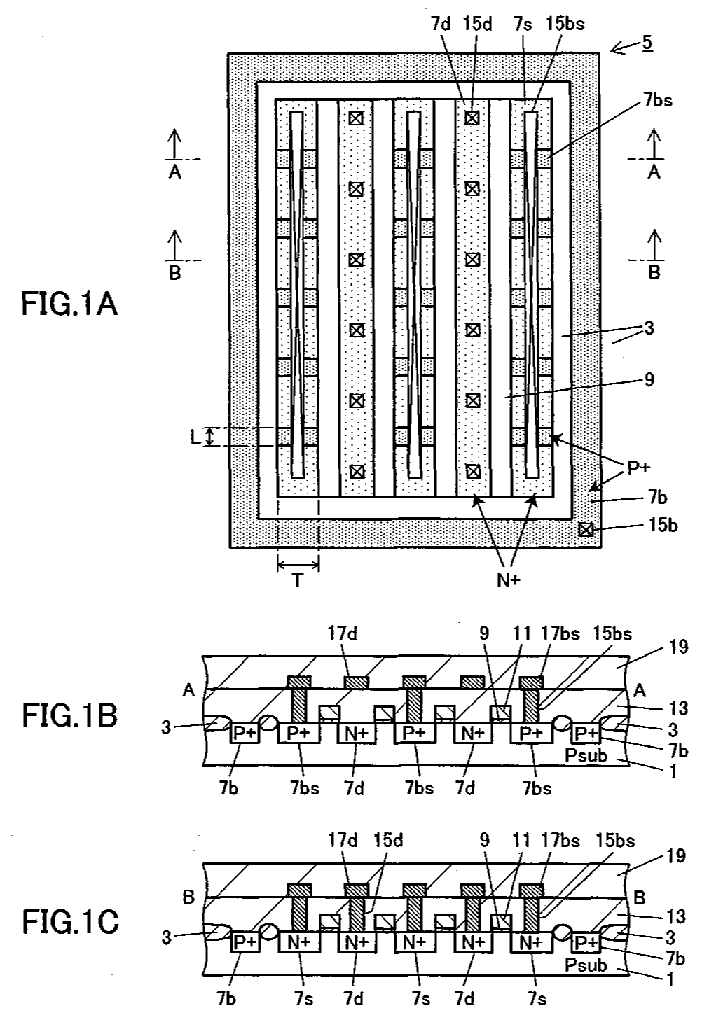

FIGS. 1A-1C illustrate an embodiment of the present invention. FIG. 1A is a plan view of a driver transistor forming area, FIG. 1B is a cross-sectional view taken along line A-A of FIG. 1A, and FIG. 1C is a cross-sectional view taken along line B-B of FIG. 1A. A gate electrode, an interlayer insulating film, a metal wiring layer, and a final protection film are omitted from FIG. 1A.

A LOCOS oxide film 3 is formed on a P-type silicon substrate 1 to define a driver transistor forming area 5. Sources 7s and drains 7d configured with N-type impurity diffusion layers are formed in the driver transistor forming area 5 on the silicon substrate 1. The sources 7s and the drains 7d are arranged alternately with intervals therebetween in the widthwise direction.

In between the sources 7s and the drains 7d, gate electrodes 11 made of polysilicon are formed on the silicon substrate 1 via gate oxide films 9. The gate electrodes 11 are formed in areas between the plural sources 7s and drains 7d. There are four gate electrodes 11 illustrated in FIGS. 1B and 1C; however, several tens of the gate electrodes 11 are generally provided in order to make the driver transistor have a sufficiently wide channel.

On the silicon substrate 1, a back gate diffusion layer 7b configured with a P-type impurity diffusion layer surrounds the area where the sources 7s and the drains 7d are formed.

Inside the sources 7s are provided plural insular P-type back gate diffusion layers 7bs in contact with the silicon substrate 1. The P-type back gate diffusion layers 7bs are spaced apart and arranged in each of the sources 7s. The top-view shape of each of the back gate diffusion layers 7bs is substantially rectangular, having a lengthwise direction orthogonal to the lengthwise direction of each of the sources 7c. A size T of the back gate diffusion layer 7bs in the lengthwise direction is the same as the size of the width of the source 7s, which is, for example, 1.0 μm. A size L of the back gate diffusion layer 7bs in the widthwise direction is, for example, 0.4 μm. In FIGS. 1A-1C, the top-view shape of the back gate diffusion layer 7bs is rectangular, which is the shape of a reticle used in a photolithography process. When the back gate diffusion layer 7bs is actually fabricated by forming a resist pattern, injecting ions, and diffusing heat in a photolithography process, the top-view shape of the back gate diffusion layer 7bs has curved angles, or is circular, or oval.

An interlayer insulating film 13 is formed on the entire surface of the silicon substrate 1, including the area where the sources 7s, the drains 7d, the back gate diffusion layers 7b, 7bs, and the gate electrodes 11 are formed. In the interlayer insulating film 13 and above each of the sources 7s, a groove-shaped contact hole 15bs is located above and extending across the plural back gate diffusion layers 7bs and the source 7s. The width of the contact hole 15bs is, for example, 0.4 μm. In the interlayer insulating film 13 and above each of the drains 7d, a groove-shaped contact hole 15d is formed. In the interlayer insulating film 13 and above the back gate diffusion layer 7b, a contact hole 15b is formed. In the interlayer insulating film 13 and above each of the gate electrodes 11, contact holes are formed (not shown).

A comb-like metal wiring layer 17bs is formed on the interlayer insulating film 13 including areas where the contact holes 15bs are formed above the sources 7s and the back gate diffusion layers 7bs. The plural sources 7s and the back gate diffusion layers 7bsare electrically connected with each other via the contact holes 15bs and the metal wiring layer 17bs.

A metal wiring layer (not shown) is formed on the interlayer insulating film 13 including an area where the contact hole 15b is formed above the back gate diffusion layer 7b.

A comb-like metal wiring layer 17d is formed on the interlayer insulating film 13 including areas where the contact holes 15d are formed above the drains 7d. The plural drains 7d are electrically connected with each other via the contact holes 15d and the metal wiring layer 17d.

A metal wiring layer is formed in an area including the contact holes (not shown) above the gate electrodes 11. The plural gate electrodes 11 are electrically connected with each other via the not shown contact holes and the metal wiring layer.

A final protection film 19 is formed on the interlayer insulating film 13.

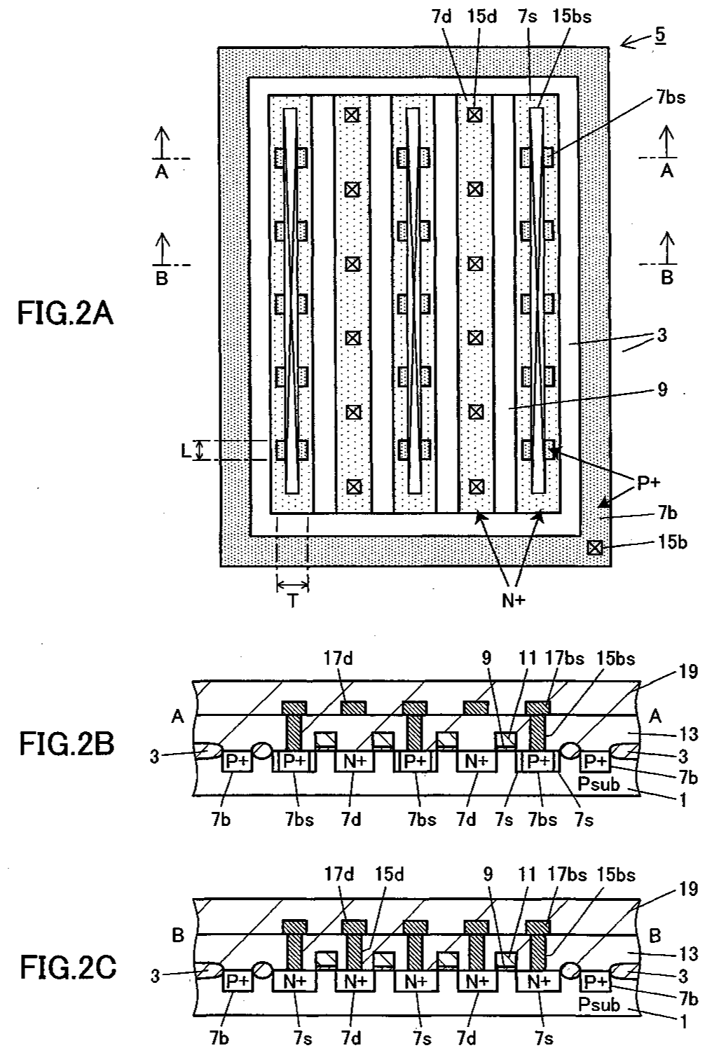

FIGS. 2A-2C illustrate another embodiment of the present invention. FIG. 2A is a plan view of the driver transistor forming area, FIG. 2B is a cross-sectional view taken along line A-A of FIG. 2A, and FIG. 2C is a cross-sectional view taken along line B-B of FIG. 2A. In FIGS. 2A-2C, elements corresponding to those in FIGS. 1A-1C are denoted by the same reference numbers, and are not further described.

In the present embodiment, the difference between the embodiment shown in FIGS. 1A-1C is that the size T of the back gate diffusion layer 7bs in the lengthwise direction is less than the width of the source 7s (1.0 μm). The size T is, for example, 0.8 μm. The size L of the back gate diffusion layer 7bs in the widthwise direction is, for example, 0.4 μm. In this manner, the size T of the back gate diffusion layer 7bscorresponding to the widthwise direction of the source 7s can be less than the width of the source 7s.

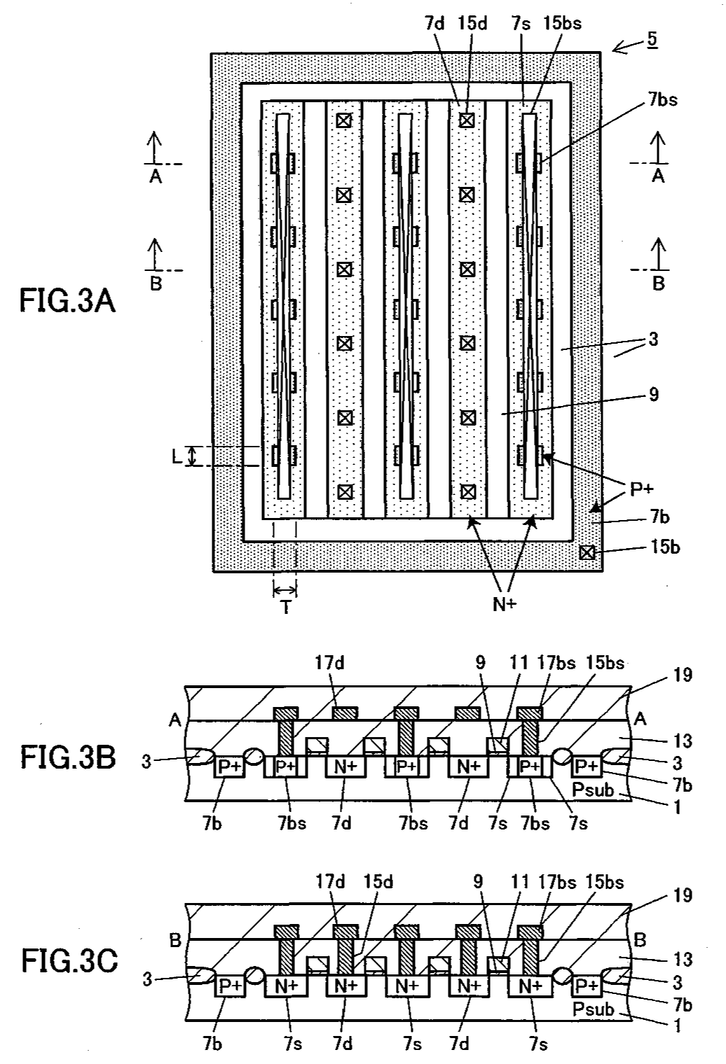

FIGS. 3A-3C illustrate yet another embodiment of the present invention. FIG. 3A is a plan view of the driver transistor forming area, FIG. 3B is a cross-sectional view taken along line A-A of FIG. 3A, and FIG. 3C is a cross-sectional view taken along line B-B of FIG. 3A. In FIGS. 3A-3C, elements corresponding to those in FIGS. 1A-1C are denoted by the same reference numbers, and are not further described.

In the present embodiment, the size T of the back gate diffusion layer 7bs in the lengthwise direction is even less than that of the embodiment shown in FIGS. 2A-2C. The size T is, for example, 0.6 μm.

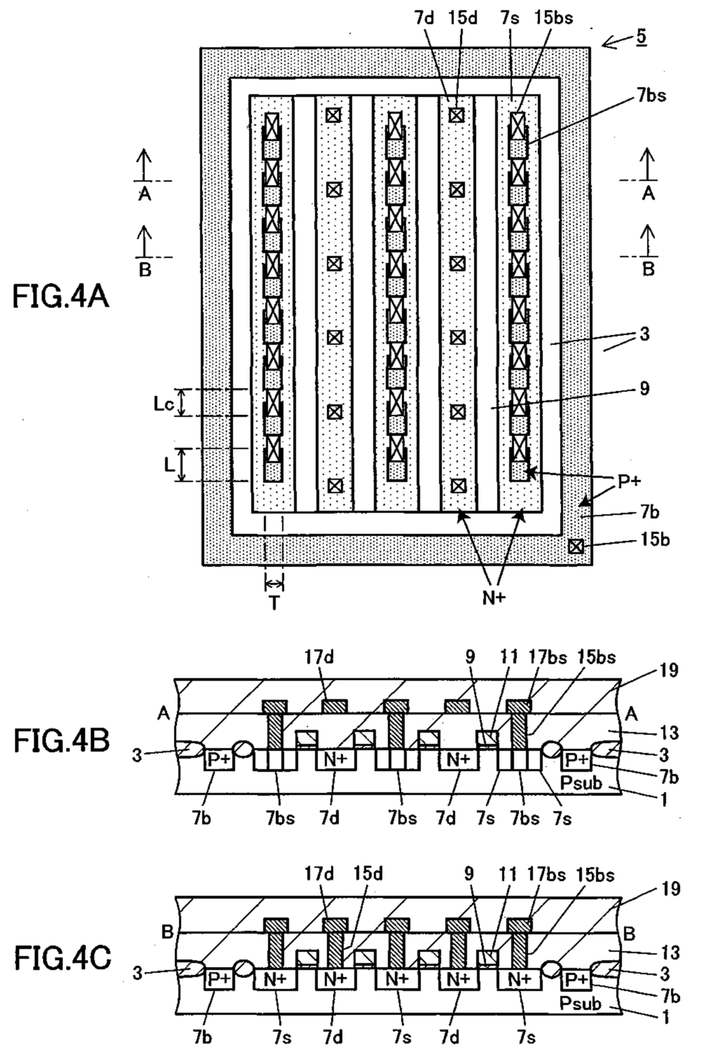

FIGS. 4A-4C illustrate yet another embodiment of the present invention. FIG. 4A is a plan view of the driver transistor forming area, FIG. 4B is a cross-sectional view taken along line A-A of FIG. 4A, and FIG. 4C is a cross-sectional view taken along line B-B of FIG. 4A. In FIGS. 4A-4C, elements corresponding to those in FIGS. 1A-1C are denoted by the same reference numbers, and are not further described.

In the present embodiment, the difference between the embodiment shown in FIGS. 1A-1C is that the lengthwise direction and the widthwise direction of the back gate diffusion layers 7bs are reversed. The size T of the back gate diffusion layer 7bs in the widthwise direction is less than the width of the source 7s (1.0 μm). The size T is, for example, 0.4 μm. The size L of the back gate diffusion layer 7bs in the lengthwise direction is, for example, 1.0 μm. The back gate diffusion layers 7bs are arranged with intervals of, for example, 0.4 μm.

Plural contact holes 15bs are formed on each of the sources 7s. Each of the contact holes 15bs extends across one of the back gate diffusion layers 7bs and part of the source 7s. For example, a size Lc of the contact hole 15bs in the lengthwise direction is 0.8 μm and a size of the contact hole 15bs in the widthwise direction is 0.4 μm, which is the same as the size T of the back gate diffusion layer 7bs in the widthwise direction. In FIG. 4A, the width of the back gate diffusion layer 7bs is illustrated to appear longer than the width of the contact hole 15bs as a matter of convenience.

In this manner, the lengthwise direction of the back gate diffusion layer 7bs can be the same as the lengthwise direction of the source 7s. Furthermore, the contact hole 15bs does not need to be groove-shaped as in the embodiment shown in FIGS. 1A-1C. Instead, plural contact holes 15bs can be provided on each of the sources 7s.

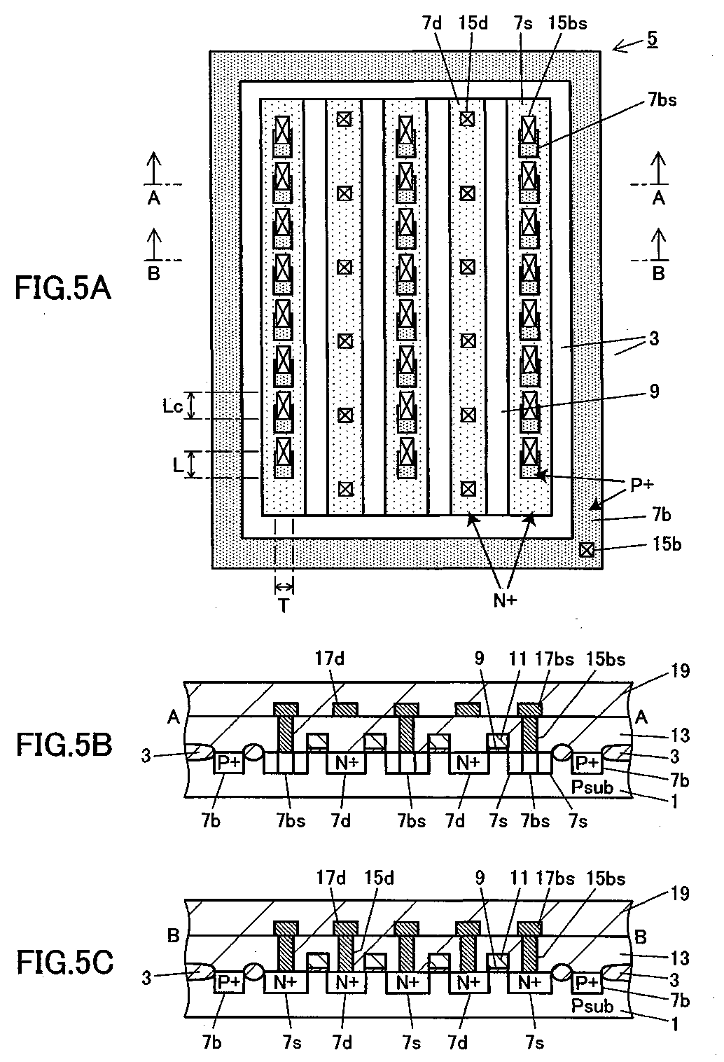

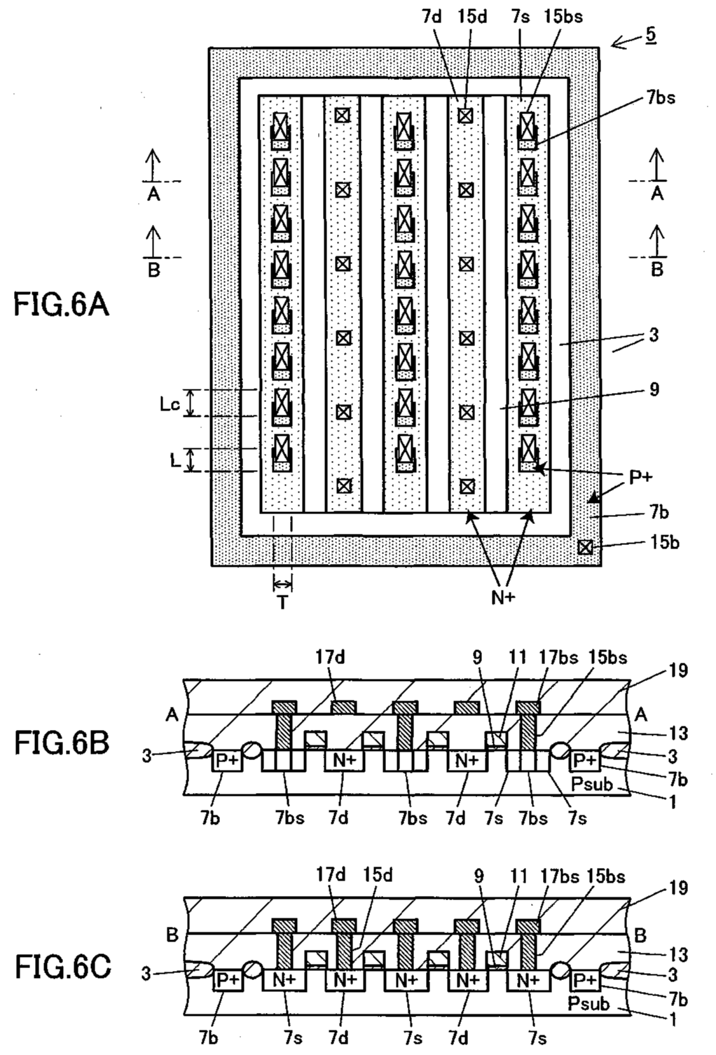

FIGS. 5A-5C and FIGS. 6A-6C illustrate other embodiments of the present invention. FIGS. 5A, 6A are plan views of the driver transistor forming area, FIGS. SB and 6B are cross-sectional views taken along line A-A of FIGS. 5A and 6A, and FIGS. 5C and 6C are cross-sectional views taken along line B-B of FIGS. 5A and 6A, respectively. In FIGS. 5A-5C and FIGS. 6A-6C, elements corresponding to those in FIGS. 1A-1C are denoted by the same reference numbers, and are not further described.

In the embodiment shown in FIGS. 5A-5C, the size L of the back gate diffusion layer 7bs in the lengthwise direction is less than that of the embodiment shown in FIGS. 4A-4C. The size L is, for example, 0.8 μm.

In the embodiment shown in FIGS. 6A-6C, the size L of the back gate diffusion layer 7bs in the lengthwise direction is even less than that of the embodiments shown in FIGS. 4A-4C and FIGS. 5A-5C. The size L is, for example, 0.6 μm. In both of the embodiments shown in FIGS. 5A-5C and FIGS. 6A-6C, the size T of the back gate diffusion layer 7bs in the widthwise direction is 0.4 μm.

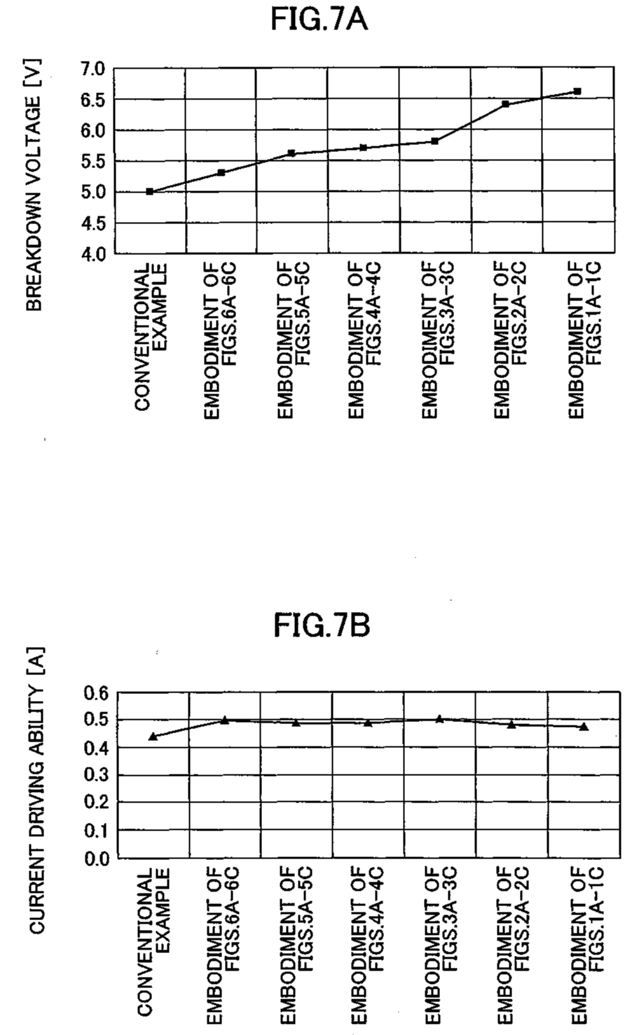

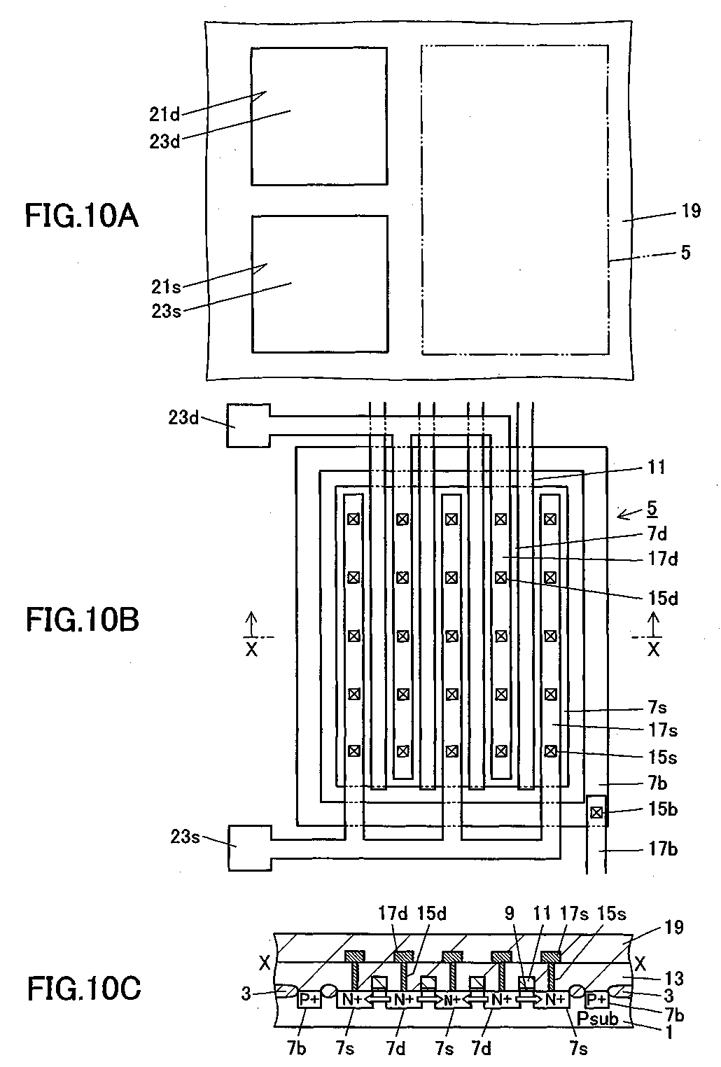

FIGS. 7A, 7B are graphs illustrating results obtained by measuring the voltage at which the parasitic bipolar transistor starts operating (breakdown voltage) and the current driving ability of the embodiments of the present invention and a conventional example. FIG. 7A illustrates the breakdown voltages and FIG. 7B illustrates the current driving abilities. The unit of measure of the vertical axis is volts (V) in FIG. 7A and is amperes (A) in FIG. 7B. Samples of the present invention are based on the structures illustrated in FIGS. 1A-6C, and the sample of the conventional example is based on the structure shown in FIGS. 10A-10C.

As shown in FIGS. 7A, 7B, with the driver transistor according to the embodiments of the present invention, the breakdown voltage of the parasitic bipolar transistor can be made higher and the current driving ability can be prevented from decreasing compared to the conventional example. Furthermore, these test results show that the current driving ability can be increased compared to the conventional example.

Results shown in FIGS. 7A, 7B say that higher breakdown voltages can be attained when the contact hole 15bs is groove-shaped and the lengthwise direction of the back gate diffusion layer 7bs is in the widthwise direction of the source 7s (i.e., the embodiments shown in FIGS. 1A-3C). In particular, it was found that when the size of the back gate diffusion layer 7bs in the lengthwise direction is the same as the width of the source 7s (i.e., the embodiment shown in FIGS. 1A-1C), the highest breakdown voltage can be attained.

In the embodiments shown in FIGS. 1A-3C, the groove-shaped contact hole 15bs is located above and extends across the plural back gate diffusion layers 7bs and the source 7s. However, as described in the embodiments shown in FIGS. 4A-6C, there can be plural contact holes 15bs formed on the source 7s, with each of the contact holes 15bs extending across one of the back gate diffusion layers 7bs and part of the source 7s.

In the embodiments shown in FIGS. 4A-6C, plural contact holes 15bs are formed on each of the sources 7s, and each of the contact holes 15bs extends across one of the back gate diffusion layers 7bs and part of the source 7s. However, as described in the embodiments shown in FIGS. 1A-3C, the groove-shaped contact hole 15bs can be located above and extending across the plural back gate diffusion layers 7bs and the source 7s.

In the embodiments shown in FIGS. 1A-6C, the back gate diffusion layers 7bs are substantially rectangular; however, the back gate diffusion layers 7bs can be substantially square-shaped.

In the embodiments shown in FIGS. 1A-6C, the present invention is applied to an N channel type MOS transistor; however, it is obvious that the present invention can also be applied to a P channel type MOS transistor.

In the above embodiments, a P-type silicon substrate is employed; however, an N-type silicon substrate can also be employed.

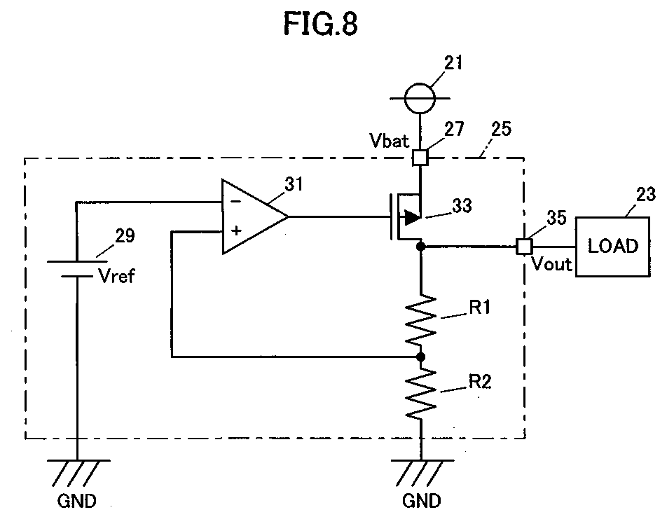

FIG. 8 is a circuit diagram of an embodiment of a semiconductor device provided with a constant-voltage generating circuit, which is an analog circuit.

A constant voltage generating circuit 25 is provided so as to stably supply power from a direct current power supply 21 to a load 23. The constant voltage generating circuit 25 includes an input terminal (Vbat) 27 to which the direct current power supply 21 is connected, a reference voltage generating circuit (Vref) 29, an operational amplifier (comparator) 31, a P channel type MOS transistor (hereinafter abbreviated as “PMOS”) 33 configuring an output driver, dividing resistors R1, R2, and an output terminal (Vout) 35. The driver transistor configuring an embodiment of the present invention is applied to the PMOS 33. In this case, the source and the substrate potential of the driver transistor are connected to the input terminal 27.

Details of the operational amplifier 31 of the constant voltage generating circuit 25 are described as follows. An output terminal of the operational amplifier 31 is connected to a gate electrode of the PMOS 33. A reference voltage Vref is applied from the reference voltage generating circuit 29 to an inverting input terminal (−) of the operational amplifier 31. A voltage obtained by dividing an output voltage (Vout) with the dividing resistors R1, R2 is applied to a noninverting input terminal (+) of the operational amplifier 31. The voltage divided by the dividing resistors R1, R2 is controlled so as to be equal to the reference voltage Vref.

With the driver transistor according to an embodiment of the present invention, the breakdown voltage of the parasitic bipolar transistor can be made higher and the current driving ability can be prevented from decreasing. Accordingly, it is possible to form a highly reliable constant voltage generating circuit 25 that has high current driving ability.

According to one embodiment of the present invention, a driver transistor can be formed, in which the voltage at which a parasitic bipolar transistor of the driver transistor starts operating is made high (high breakdown voltage) without decreasing the current driving ability of the driver transistor.

Further, according to one embodiment of the present invention, the breakdown voltage of the driver transistor can be made even higher.

Further, according to one embodiment of the present invention, a semiconductor device including a highly reliable constant voltage generating circuit that has high current driving ability can be formed.

The present invention is not limited to the specifically disclosed embodiment, and variations and expansions may be made without departing from the scope of the present invention.

The present application is based on Japanese Priority Patent Application No. 2006-098393, filed on Mar. 31, 2006, the entire contents of which are hereby incorporated by reference.

1. A semiconductor device comprising:
a driver transistor including
a source and a drain of a second conductive type provided with an interval therebetween in a semiconductor substrate of a first conductive type,
a gate electrode extending in a predetermined direction and provided on the semiconductor substrate via a gate insulating film between the source and the drain,
plural insular back gate diffusion layers of the first conductive type provided in the source so as to be in contact with the semiconductor substrate, wherein the back gate diffusion layers are spaced apart and arranged in the predetermined direction in the source, and
a contact hole extending in the predetermined direction on the source and at least one of the back gate diffusion layers.

2. The semiconductor device according to claim 1, wherein the contact hole is groove-shaped and extends on the source and across the back gate diffusion layers.

3. The semiconductor device according to claim 1, wherein a top-view shape of each of the back gate diffusion layers is substantially rectangular, and
a lengthwise direction of each of the back gate diffusion layers is orthogonal to a lengthwise direction of the source.

4. The semiconductor device according to claim 3, wherein a lengthwise size of each of the back gate diffusion layers is equal to a widthwise size of the source.

5. A semiconductor device comprising:
a constant voltage generating circuit including
an output driver configured to control output of an input voltage,
a dividing resistor configured to divide an output voltage and output the divided output voltage,
a reference voltage generating circuit configured to output a reference voltage,
a comparator configured to compare the divided output voltage received from the dividing resistor and the reference voltage received from the reference voltage generating circuit and control the output driver according to a comparison result; wherein
the output driver is the driver transistor in the semiconductor device according to claim 1.
